(19) United States
(12) Patent Application Publication
(10) Pub. No.: US 2007/0232072 A1
(43) Pub. Date: Oct. 4, 2007

(54) FORMATION OF PROTECTION LAYER ON WAFER TO PREVENT STAIN FORMATION

(76) Inventors: Bo Zheng, Saratoga, CA (US); Hung X. Hoang, San Jose, CA (US); Methelyn F. Murphy, Austin, TX (US)

Correspondence Address: PATTERSON & SHERIDAN, LLP, 3040 POST OAK BOULEVARD, SUITE 1500, HOUSTON, TX, 77056, US

(21) Appl. No.: 11/567,595

(22) Filed: Dec. 6, 2006

Related U.S. Application Data
(63) Continuation-in-part of application No. 10/826,487, filed on Apr. 16, 2004, now abandoned.
(60) Provisional application No. 60/463,859, filed on Apr. 18, 2003.

(51) Int. Cl. H01L 21/302

(52) U.S. Cl. 438/695; 257/E21.214; 257/E21.219

(57) ABSTRACT

Embodiments of the invention generally provide an apparatus and a method for cleaning the bevel edge of a semiconductor substrate, while simultaneously providing a protection layer over the production surface of the substrate. The method for forming the protection layer generally includes rotating the semiconductor substrate on a substrate support member, dispensing an etching solution onto the bevel of the substrate with a first pivotally mounted fluid dispensing nozzle, and dispensing a protective fluid onto a central portion of the substrate simultaneously with the dispensing of the etching solution with a second pivotally mounted fluid dispensing nozzle.

### CROSS-REFERENCE TO RELATED APPLICATIONS

This application is a continuation-in-part of U.S. patent application Ser. No. 10/826,487, filed Apr. 16, 2004 which claims benefit of U.S. Provisional Patent Application Ser. No. 60/463,859, filed Apr. 18, 2003. Each of the above aforementioned related patent applications is hereby incorporated by reference.

### BACKGROUND OF THE INVENTION

1. Field of the Invention

Embodiments of the invention generally relate to a method for cleaning a bevel of a substrate after a semiconductor processing step has been conducted on the substrate while protecting the production surface of the substrate.

2. Description of the Related Art

Metallization of sub-quarter micron sized features is a foundational technology for present and future generations of integrated circuit manufacturing processes. Plating techniques, i.e., electrochemical plating (ECP) and electroless plating, have emerged as promising processes for void free filling of sub-quarter micron sized high aspect ratio interconnect features in integrated circuit manufacturing processes.

Once the plating process is completed, the substrate is generally transferred to at least one of a substrate rinsing cell or a bevel edge clean cell. Bevel edge clean cells are generally configured to dispense an etching solution onto the perimeter or bevel of the substrate to remove unwanted metal plated thereon. The substrate rinse cells, often called spin rinse dry cells, generally operate to rinse the surface of the substrate (both front and back) with a rinsing solution to remove any contaminants therefrom. Further, the rinse cells are often configured to spin the substrate at a high rate of speed in order to spin off any remaining fluid droplets adhering to the substrate surface. Once the remaining fluid droplets are spun off, the substrate is generally clean and dry, and therefore, ready for transfer from the ECP tool. The bevel clean cells dispense an etching solution onto the bevel edge of the substrate to remove any unwanted deposits from the bevel and exclusion zone of the substrate.

However, one challenge associated with bevel clean processes is that the etching solution may sometimes splash back onto the production surface of the substrate during the edge cleaning process, which generally causes a defect in the production surface. Further, the airflow in the bevel clean cell (generally a result of the rotation of the substrate during the bevel clean process) has also been known to carry droplets or micro-droplets of the etching solution back onto the production surface, which as noted above, causes defects. Therefore, there is a need for a method for protecting the production surface of the substrate during a bevel cleaning process. Additionally, there is a need for a method for protecting the substrate surface during the edge bead removal process that also does not interfere or dilute the etching solution or otherwise detrimentally effect the transition profile of the substrate.

Embodiments of the invention generally provide a bevel clean method configured to protect the production surface of a substrate during a bevel cleaning process.

### SUMMARY OF THE INVENTION

Embodiments of the invention generally provide a method for cleaning a bevel of a semiconductor substrate while protecting the production surface from cleaning solution splash.

One embodiment of the present invention provides a method for cleaning a bevel edge of a semiconductor substrate comprising centering the semiconductor substrate on a central axis of a substrate support member, rotating the semiconductor substrate on the substrate support member about the central axis, dispensing an etching solution onto the bevel edge of a production surface of the semiconductor substrate with a first pivotally mounted fluid dispensing nozzle, and simultaneously with the dispensing of the etching solution, dispensing a protective fluid onto a central portion of the production surface with a second pivotally mounted fluid dispensing nozzle.

Another embodiment of the present invention provides a method for removing unwanted metal deposits from a bevel edge of a substrate comprising centering the substrate on a central axis of a substrate support member, securing the substrate on the substrate support member, rotating the substrate on the substrate support member about the central axis at a rate of between about 50 rpm and about 400 rpm, dispensing a protective fluid onto a production surface of the substrate, and dispensing an edge bead removal solution onto the bevel edge of the production surface simultaneously with the dispensing of the protective fluid.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a top plan view of one embodiment of an electrochemical plating system of the invention.

FIG. 2 illustrates a top perspective view of an exemplary bevel clean cell of the invention.

FIG. 3 illustrates a top perspective view of an exemplary backside fluid dispensing manifold of the invention.

FIG. 4 illustrates a perspective view of an exemplary substrate centering mechanism of the invention.

FIG. 5A illustrates a sectional view of an exemplary substrate centering member of the invention.

FIG. 5B illustrates a top view of an exemplary substrate centering member of the invention.

FIG. 6 illustrates an exemplary bevel edge cleaning process in accordance with one embodiment of the present invention.

### DETAILED DESCRIPTION OF THE PREFERRED EMBODIMENT

Embodiments of the invention generally provide a method to be used in a multi-chemistry electrochemical plating system configured to plate conductive materials onto semiconductor substrates. The plating system generally includes a substrate loading area in communication with a substrate processing platform. The loading area is generally configured to receive substrate containing cassettes and transfer substrates received from the cassettes into the plating system for processing. The loading area generally includes a robot configured to transfer substrates to and from the cassettes and to the processing platform or a substrate annealing chamber positioned in communication with the loading area. The processing platform generally includes at least one substrate transfer robot and a plurality of substrate processing cells, i.e., ECP cells, bevel clean cells, spin rinse dry cells, substrate cleaning cells, and electroless plating cells.

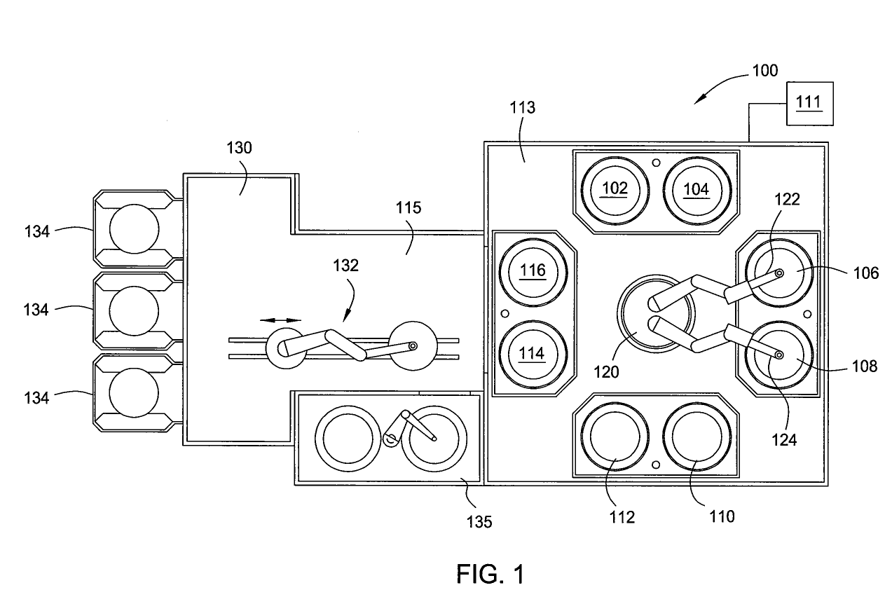

FIG. 1 illustrates a top plan view of an ECP system 100 of the invention. The ECP system 100 includes a factory interface (FI) 130, which is also generally termed a substrate loading station. The factory interface 130 includes a plurality of substrate loading stations configured to interface with substrate containing cassettes 134. A robot 132 is positioned in the factory interface 130 and is configured to access substrates contained in the substrate containing cassettes 134. Further, the robot 132 also extends into a link tunnel 115 that connects the factory interface 130 to a processing mainframe or a platform 113. The position of the robot 132 allows the robot 132 to access substrate containing cassettes 134 to retrieve substrates therefrom and then deliver the substrates to one of the processing locations 114, 116 positioned on the platform 113, or alternatively, to an annealing station 135. Similarly, the robot 132 may be used to retrieve substrates from the processing locations 114, 116 or the annealing station 135 after a substrate processing sequence is complete. In this situation, the robot 132 may deliver the substrate back to one of the substrate containing cassettes 134 for removal from the ECP system 100.

As mentioned above, the ECP system 100 also comprises the platform 113 having a substrate transfer robot 120 centrally positioned thereon. The robot 120 may comprises one or more arms/blades 122, 124 configured to support and transfer substrates thereon. Additionally, the robot 120 and the accompanying blades 122, 124 are generally configured to extend, rotate, and vertically move so that the robot 120 may insert and remove substrates to and from a plurality of processing locations 102, 104, 106, 108, 110, 112, 114, 116 positioned on the platform 113. Similarly, the robot 132 in the factory interface 130 also includes the ability to rotate, extend, and vertically move its substrate support blade, while also allowing for linear travel along the robot track that extends from the factory interface 130 to the platform 113.

Generally, the processing locations 102, 104, 106, 108, 110, 112, 114, 116 may be any number of processing cells utilized in an electrochemical plating platform. More particularly, the process locations may be configured as electrochemical plating cells, rinsing cells, bevel clean cells, spin rinse dry cells, substrate surface cleaning cells, electroless plating cells, metrology inspection stations, and/or other processing cells that may be beneficially used in conjunction with a plating platform. Each of the respective processing cells and robots are generally in communication with a process controller 111, which may be a microprocessor-based control system configured to receive inputs from both a user and/or various sensors positioned on the ECP system 100 and appropriately control the operation of the ECP system 100 in accordance with the inputs.

In the ECP system 100 illustrated in FIG. 1, the processing locations may be configured as follows. The processing locations 114 and 116 may be configured as an interface between the wet processing stations on the platform 113 and the dry processing regions in the link tunnel 115, the annealing station 135, and the factory interface 130. The processing cells located at the interface locations may be spin rinse dry cells and/or substrate cleaning cells. More particularly, each of the processing locations 114 and 116 may include both a spin rinse dry cell and a substrate cleaning cell in a stacked configuration. Locations 102, 104, 110, and 112 may be configured as plating cells, either electrochemical plating cells or electroless plating cells, for example. Processing locations 106, 108 may be configured as substrate bevel cleaning cells. Additional configurations and implementations of an electrochemical processing system are illustrated in commonly assigned U.S. patent application Ser. No. 10/435,121 filed on Dec. 19, 2002 entitled “Multi-Chemistry Electrochemical Processing System”, which is incorporated herein by reference in its entirety.

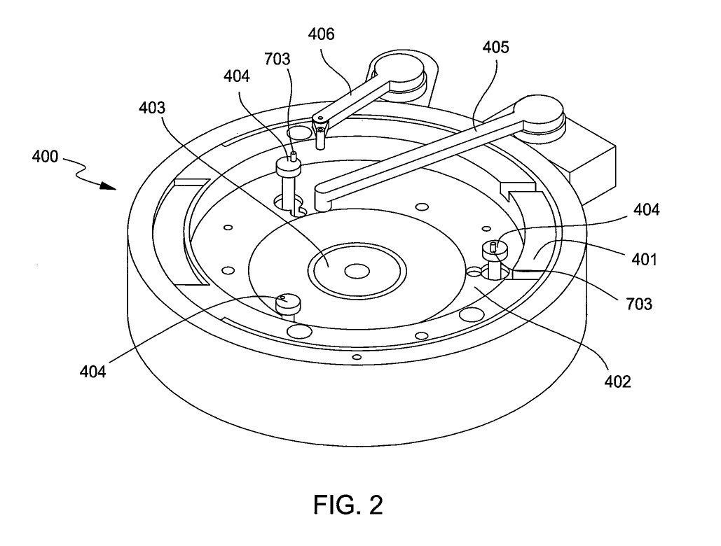

FIG. 2 illustrates a top perspective view of an exemplary bevel clean cell 400 of the invention. As noted above, the bevel clean cell 400 may be positioned at any one of the processing locations 102, 104, 106, 108, 110, 112, 114, and 116, indicated on the ECP system 100. However, in the present exemplary embodiment of the invention, the bevel clean cells 400 are generally positioned at the processing locations 106 and 108. FIG. 2 is a top perspective view of the exemplary bevel clean cell 400, and FIG. 2 generally illustrates the upper components of the exemplary bevel clean cell 400. These components generally include a cell bowl or chamber having an upstanding wall 401 and a drain basin 402 in communication with the lower portion of the upstanding wall 401. The drain basin 402 is generally configured to receive a processing fluid thereon, and channel the processing fluid to a fluid drain (not shown).

A central portion of basin 402 includes a substrate chuck 403. The substrate chuck 403, which generally may be any type of substrate chuck used in semiconductor processing, is configured to be rotatable and/or vertically actuatable. More particularly, the substrate chuck 403 may be a vacuum chuck having at least one vacuum aperture formed into the upper surface thereof, wherein the vacuum aperture is selectively in fluid communication with a vacuum source, such that the vacuum source and vacuum aperture may cooperatively operate to secure a substrate to the substrate chuck 403 via application of negative pressure to a volume between the substrate chuck 403. The substrate chuck 403 is generally supported by a mechanical mechanism positioned below the drain basin 402, wherein the mechanical mechanism is configured to impart both rotational movement to the substrate chuck 403, as well as optional vertical movement to the substrate chuck 403, i.e., the mechanical mechanism is configured to optionally raise and lower the substrate chuck 403 to engage and disengage substrates positioned on the centering posts 404, as will be further discussed herein.

Further, the drain basin 402 may include a shield or cover positioned over the surface of the drain basin 402, wherein the shield or cover includes apertures formed therein for components that extend upward therethrough.

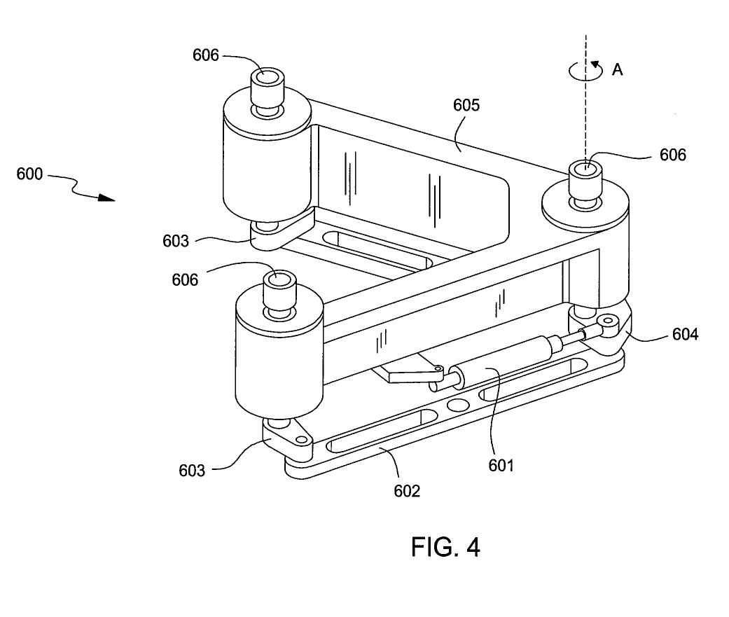

The drain basin 402 comprises a plurality of centering posts 404 extending upward therefrom. The centering posts 404 are generally positioned radially around the perimeter of the drain basin 402 in an equal spacing arrangement, for example. However, the centering posts 404 may be positioned in any desired spacing arrangement. For example, in the embodiment illustrated in FIG. 4, three centering posts 404 are positioned around the perimeter of the drain basin 402 at 120° increments. However, the centering posts 404 may be positioned at 20°, 180, and 340°, for example. The substrate centering posts 404 are generally supported by a substrate centering mechanism positioned below basin 402, which will be further discussed herein, that is configured to both vertically actuate the centering posts 404 and rotationally actuate the centering posts 404 about a longitudinal axis of each of the centering posts 404, which generally corresponds with the rotational center of each of the centering posts 404.

The bevel clean cell 400 further comprises at least one rinsing solution dispensing arm 405, along with at least one etching solution dispensing arm 406. Generally, both arms 405 and 406 are pivotally amounted to a perimeter portion of the bevel clean cell 400, and include a longitudinally extending arm having at least one fluid dispensing nozzle positioned on a distal terminating in thereof. The nozzles are positioned to dispense the respective processing fluids onto a first or upper side of a substrate positioned on the substrate chuck 403. More particularly, when the bevel clean cell 400 is configured as a face-up processing cell, i.e., when substrates are positioned in the bevel clean cell 400 with a production surface facing away from the drain basin 402, then the fluid dispensing nozzles are configured to dispense their respective fluids onto the production surface of the substrate. The operation of arms 405 and 406 is generally controlled the by a system controller, which is configured to precisely position (via pivotal actuation and/or vertical actuation of the respective arms) the distal end of the respective arms over a specified radial position of a substrate being processed, which allows for fluid dispensed from the nozzles positioned at the respective ends of the arms to be dispensed onto precise radial locations of a substrate being processed in the bevel clean cell 400.

Additionally, although two arms are illustrated in the present exemplary embodiment for separately dispensing the rinsing solution, which may be deionized water, and an etching solution, which may be an acid, embodiments of the invention are not intended to be limited to any particular number of fluid dispensing arms. More particularly, other embodiments of the invention may implement a single pivotally amounted to arm having both rinsing solution dispensing nozzles and etching solution dispensing nozzles positioned to thereon.

In this configuration, however, the placement of the respective rinsing solution nozzles and the etching solution nozzles becomes more important, as bevel clean processes generally require precise dispensing of the etching solution onto an exclusion zone of the substrate being processed, i.e., onto the outer 2-5 mm perimeter of the substrate. Further, each of arms 405 and 406 may include a mechanism configured to prevent fluid dripping from the nozzles when the nozzles are not activated from touching the substrate. For example, the nozzles may include a vacuum port or suck up valve (not shown) that is configured to receive unwanted fluid drips during off times. Alternatively, nozzles may include a gas aperture that is configured to blow unwanted droplets of fluid away from the substrate surface.

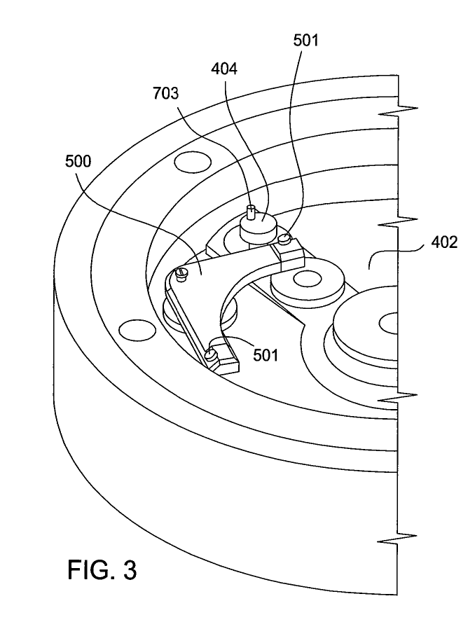

FIG. 3 illustrates a top perspective view of an exemplary backside fluid dispensing manifold 500 of the invention. The backside fluid dispensing manifold 500 is generally positioned on the drain basin 402 between the substrate centering posts 404. The manifold 500 generally includes a V-shaped structure having two distal terminating ends. Each of the respective ends includes a fluid dispensing nozzle 501 positioned to thereon. The manifold 500 may be vertically actuated and pivotally actuated to particularly position the respective fluid dispensing nozzles 501 with respect to the substrate being processed the bevel clean cell 400. This configuration allows for the pivotally mounted fluid dispensing arms 405 and 406 to dispense processing fluids onto the production or front side of the substrate, while the manifold 500 may simultaneously dispense processing fluids onto the nonproduction or backside of the substrate.

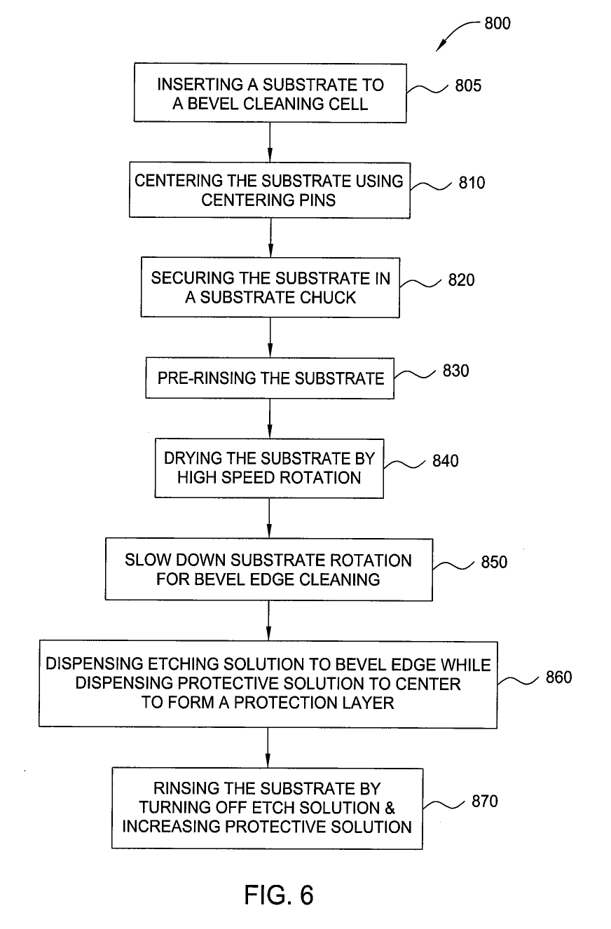

FIG. 4 illustrates a perspective view of an exemplary substrate centering mechanism 600 in accordance with one embodiment of the present invention. The substrate centering mechanism 600 is generally positioned below the drain basin 402, and comprises a frame member 605 having a plurality of receptacles 606 configured to receive and secure the centering posts 404 therein. The frame member 605 may be in communication with an actuation mechanism configured to move the frame member 605 and the associated components, i.e., to raise and lower the frame member 605. In the illustrated exemplary embodiment, the frame member 605 comprises three receptacles 606 configured to receive the centering posts 404. A lower portion of each of the receptacles 606 extends through the frame member 605 out the opposing side, as illustrated in FIG. 6.

Further, each of receptacles 606 are rotatably mounted within the frame member 605, such that the receptacles 606 may be rotated in the direction indicated by arrow “A” above the receptacles, and as such, cause the centering posts 404 secured in the receptacles 606 to also rotate. With the lower portion of each of the receptacles 606 that extends below the frame member 605 generally includes an actuation arm 603 or a primary arm member 604 attached thereto. Each of the actuation arms 603 or the primary arm member 604 are also connected to one another a linkage 602, which may be a solid linkage, belt, hydraulic member, etc. Further, a selectively activated actuation device 601 is mechanically in communication with the primary arm member 604, and is configured to selectively impart pivotal movement thereto.

Since each of the receptacles 606 are rotatably mounted within their respective portions of the frame member 605, and since each of the lower extending portions of the receptacles 606 include the actuation device 601 and the linkage 602 attached thereto, actuation of the primary arm member 604 by the actuation device 601 causes pivotal movement to the a primary arm member 604, directly causes the actuation arms 603 and corresponding receptacles 606 to correspondingly pivot with the primary arm member 604. More particularly, each receptacle 606 receives a centering post 404, and when the actuation device 601 pivots via the primary arm member 604, the corresponding receptacle 606 above the primary arm member 604 is also pivoted. Further, since the linkage 602 can link the actuation arms 603 to the primary arms member 604, pivotal movement of the primary arm member 604 translates to a corresponding pivotal movement to the actuation arms 603, which directly results in pivotal or rotational movement of the receptacles 606 positioned above the actuation arms 603. This configuration allows for each of the centering posts 404 to be rotatably actuated simultaneously, and for the actuation/rotation to be identical between the three centering posts 404. Further, each of the receptacles 606 may be vertically actuated, via, for example, vertical movement of the entire substrate centering mechanism 600, or alternatively, via vertical slidable movement of the receptacles 606 within the frame member 605.

The actuation device 601 is generally an actuator configured to rotate the centering posts 404 to engage and center a substrate between the respective centering posts 404 without exerting excessive pressure on the substrate. For example, each of the centering posts 404 includes a centering pin that operates to engage and slide the substrate to a centered position, as will be further discussed herein. Once the substrate is slidably positioned at the center location, the centering pins continue to mechanically engage the substrate to maintain the substrate in the centered position. However, in conventional centering mechanisms, the strength and configuration of the actuator caused the substrate to bow as a result of the forces being applied to the perimeter of the substrate by the centering posts once the substrate was centered. Further, once the substrate bowed, even if the actuator were released, the lack of biasing pressure against the substrate by the actuator causes the substrate to shift from center. Therefore, to address this problem, the inventors have replaced the conventional actuator with a frictionless actuator as the actuation device 601. A frictionless actuator operates similarly to conventional actuators during the centering process, however, once the substrate is centered, the frictionless actuator overcomes the bowing and shifting off center challenges associated with conventional actuators. For example, once the substrate is centered, frictionless actuators can be released without movement or a substantial change in drive pressure of the frictionless actuator. Further, frictionless actuators are capable of centering the substrate without squeezing the substrate to the point of bowing. Airpot Corporation of Norwalk, Conn. manufactures instrument quality pneumatic actuators and Airpel Anti-Stiction Air Cylinders, for example, may be used to advantage as the actuation device 601. These devices are generally manufactured using a graphite piston and borosilicate glass cylinder combination in which each piston is selectively matched to fit the cylinder with extremely close tolerances. This configuration provides low friction between the cylinder and piston, and therefore the actuator is responsive to forces as low as only a few grams and actuation pressures of less than 0.2 psi. Further, the starting and running friction are nearly identical, which prevents uneven or uncontrolled starts and provides uniform smoothness throughout the full stroke of the device. As such, using the frictionless-type actuator, once the substrate is centered, the frictionless actuator may be released without encountering reverse movement or slipping of the substrate. Alternatives to the frictionless actuator comprises motors, voice coils, and electro-ceramics.

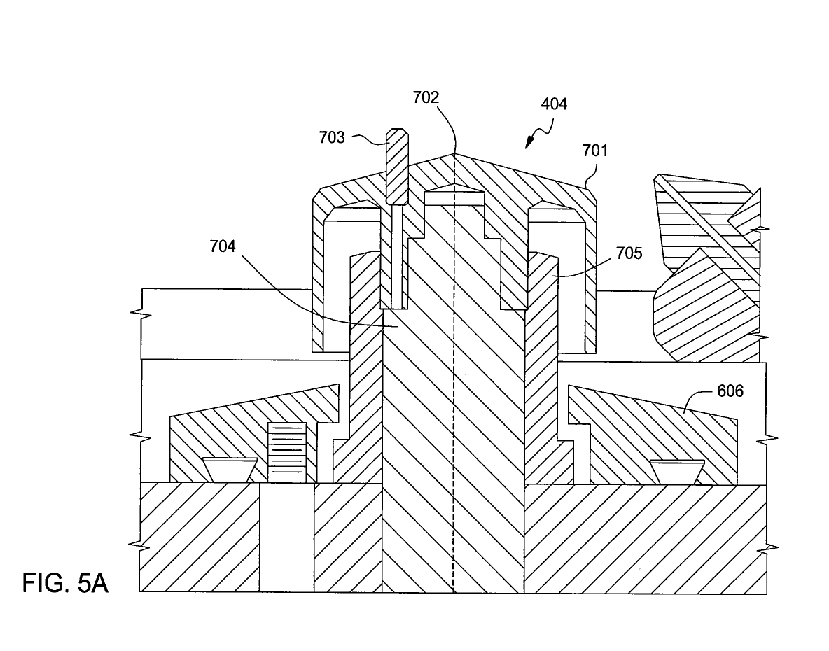

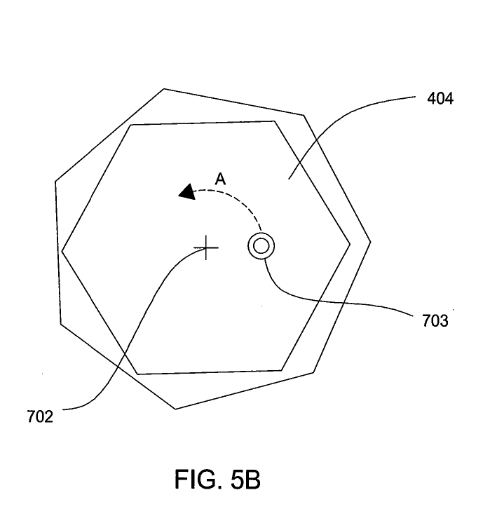

FIG. 5A illustrates a sectional view of an exemplary centering post 404 in accordance with one embodiment of the present invention. The centering post 404 is generally elongated, i.e., cylindrically shaped, and is configured to be received in the receptacles 606 of the substrate centering mechanism 600. The centering post 404 generally comprises a core 704 that has a cap member 701 that covers an upper portion of the core 704. The core 704 is generally manufactured from a rigid material, such as for example a ceramic. The cap member 701 includes a raised central portion 702 that terminates in a peak or central point. The peak or point of the central portion 702 is positioned such that it coincides with the longitudinal axis of the centering post 404. When the centering post 404 is rotated, the point or peak of the central portion 702 remains in a unitary location. The cap member 701 is generally manufactured from a rigid material that has good exposure characteristics to electrochemical processing solutions. One exemplary material that the cap member 701 may be manufactured from is PEEK.

The cap member 701 also includes a substrate centering pin 703 extending upward from an upper surface of the core 704. The substrate centering pins 703 is positioned radially outward from the central portion 702 or peak of the cap 701. In this manner, when the centering post 404 is rotated, the substrate centering pin 703 pivots or rotates around the longitudinal axis of the core 704, and as such, the substrate centering pin 703 rotates or pivots about the central portion 702.

The centering post 404 also includes a sleeve member 705 positioned radially outward of the core 704. The sleeve member 705 cooperatively engages the cap member 701 and the core 704 to form a fluid seal, which prevents processing fluids from traveling through the bore containing core member 704 and damaging the substrate centering mechanism 600 positioned below.

FIG. 5B illustrates a top view of the substrate centering post 404 of the invention, and more particularly, FIG. 5B illustrates a top view of the cap member 701 illustrated in FIG. 5A. FIG. 5B illustrates the positional relationship between the central portion 702 or peak of the central portion 702 and the substrate centering pin 703. Further, when the centering post 404 is rotated about its' central axis, i.e., rotated about the axis that extends through the central portion 702 by the substrate centering mechanism 600, then the substrate centering pin 703 is caused to move in the direction indicated by arrow A. This motion, which will be further discussed herein, may be used to urge a substrate positioned on the centering post 404 to a central or center position.

In operation, the bevel cleaning cell of the invention can be used to rinse and clean substrates. The cleaning operation may be conducted on both the production surface and the non-production surface of the substrate, or on either surface individually. The bevel cleaning cell of the invention may also be used to clean excess material from the bevel portion of the substrates, i.e., the portion of the seed layer deposited near the perimeter on the production surface, on the bevel, and partially onto the backside of the substrate. This process is often termed bevel clean or edge bead removal in the semiconductor art.

As noted above, generally, the ECP system 100 will include plating cells positioned at locations 102, 104, 110, and 112, spin rinse dry and cleaning cells stacked at the processing locations 114 and 116, and bevel clean cells positioned at locations 106 and 108. The robot 120 operates to transfer substrates between the respective processing cells. Generally, substrates transferred to the bevel cleaning cell locations 106 and 108 are transferred thereto from one of plating cell locations 102, 104, 110, and 112, as the bevel clean cells are generally configured to remove material deposited on the double portion of the substrate, as well as the backside of the substrate, prior to the substrate being transferred out of the ECP system 100.

FIG. 6 illustrates an exemplary bevel edge cleaning process 800 in accordance with one embodiment of the present invention. The bevel edge cleaning process 800 may be performed in the bevel cleaning cell 400 of the present invention.

The bevel edge cleaning process 800 starts with step 805 in which a substrate is inserted to a bevel cleaning cell, such as the bevel cleaning cell 400 of the present invention. The insertion process may be conducted by the robot 120, and includes bringing the substrate into the bevel cleaning cell 400 and lowering the substrate onto the centering posts 404. When the substrate is lowered onto the centering posts 404, the substrate is supported by the central peak or central portion 702 of the respective centering posts 404. Once the substrate is positioned on the respective centering posts 404, the robot is retracted from bevel clean cell 400.

Once the substrate is inserted into bevel cleaning cell 400, a centering process 810 is conducted. The centering of the substrate in the bevel clean cell 400 is crucial to the bevel clean process, as the tolerances for removing the edge bead material from the substrate are generally less than about 1 mm. For example, when copper is electrochemically deposited on to a semiconductor substrate, generally, the outer 3 to 5 mm perimeter of the substrate is not considered to be part of the production surface, i.e., devices are generally not formed in this outer perimeter or band, which is generally termed the exclusion zone. The exclusion zone includes an exposed portion of the seed layer where electrical contacts are generally positioned during the plating process. The seed layer deposited on to the exclusion zone generally extends onto the bevel of the substrate, and sometimes onto the backside or not production surface of the substrate. Since subsequent semiconductor processing steps will generally include contact with either the double portion of the substrate or the backside of the substrate, it is desirable to remove or clean the double and backside of the substrate, so that subsequent contact with these areas will be less likely to generate contamination particles. The removal of the material from the exclusion zone, bevel, and backside of the substrate is generally termed a bevel clean process, and includes dispensing an etching solution onto the interface between the production surface of the substrate and the exclusion zone, while also dispensing a cleaning solution onto the backside of the substrate. Therefore, since the etching solution dispensed on to the front side of the substrate is dispensed at the interface between the production surface and exclusion zone, it is critical that the substrate be properly centered, so that the etching solution will not be dispensed onto the production surface and damage devices.

The centering process may begin by activating the actuation device 601, such as a frictionless actuator, which gently rotates each of the receptacles 606. The centering posts 404 received in the receptacles 606 are cooperatively rotated, and therefore, the substrate centering pins 703 positioned on the cap member 701 rotated inwardly and cooperatively engage the edge of the substrate. This cooperative rotational movement of the substrate centering pins 703 causes the substrate to be centered among the centering posts 404. Once the substrate is centered among the centering posts 404, a gentle tensioning force may be maintained on the substrate by the centering posts 404 via continued application of actuation pressured to the actuation device 601. However, the tensioning force is calculated to be enough force to maintain the substrate in the center position, while being an insufficient force to cause blowing or deflection of the substrate surface.

Once the substrate is centered, a chucking step 820 may be performed to secure the substrate to the substrate chuck 403. The chucking process generally includes either raising the substrate chuck 403 to engage the lower surface of the substrate secured to the centering posts 404, or lowering the centering posts 404 to position the substrate on the substrate chuck 403, or a combination of raising the substrate chuck 403 and lowering the centering posts 404. The substrate chuck 403 can be a vacuum-type chuck, and therefore, when the substrate and the substrate chuck 403 are brought into physical contact with each other, reduced pressure may be generated at the surface of the substrate chuck 403 to secure the substrate thereto. Once the substrate is secured to the substrate chuck 403, the centering posts 404 may be lowered or the substrate chuck 403 may be raised, so that the substrate is supported solely by the substrate chuck 403.

After the substrate is secured in the bevel cleaning cell 400, a pre-rinse step 830 may be performed to remove undesired materials on the substrate surface, such as copper sulfate. An exemplary pre-rinse step may include pre-rinsing both of the front and backside surfaces of the substrate. The pre-rinsing process may include dispensing cleaning solution, such as DI water onto the front side of the substrate at a flow rate of between about 1000 cc/min and about 2000 cc/min, more particularly at about 1200 cc/min. In one embodiment, DI water may be dispended onto the backside of the substrate at a flow rate of between about 50 cc/min and 100 cc/min. During this pre-rinse step, the substrate may be rotated at about 300 rpm. The duration for the fluid dispensing processes may be between about eight seconds and about 20 seconds. Generally, the pre-rinsing process is configured to rinse off any residual electrolyte that may be adhering to the substrate surface as a result of the previous electrochemical plating process.

A drying step 840 is generally preformed after the pre-rinsing step 830 to remove any DI water build up near the edge of the substrate. Once the substrate is prerinsed, the rotation speed of the substrate may be increased to between about 2000 rpm and about 3500 rpm for about five seconds in order to remove any DI buildup near the edge of the substrate. More particularly, the substrate may be rotated at between about 2800 rpm to about 3000 rpm.

After the drying step 840, rotation of the substrate is slowed down in step 850 in preparation for bevel edge cleaning. The bevel edge cleaning is generally performed by applying an etching solution to the exclusion zone. By rotating the substrate, the etching solution will flow outwards and out off the substrate after contacting the substrate surface so that only the exclusion zone has contact with the etching solution. On the other hand, the etching solution needs to stay on the substrate long enough to reacts with the surface materials and to clean the bevel. Therefore, a rotation speed that assures enough stay-on time for the etching solution is generally desired. In one embodiment, the substrate rotation speed may be between about 50 rpm to about 400 rpm. More particularly, the substrate may be rotated at about 300 rpm during bevel edge cleaning.

A bevel edge cleaning step 860 may start after the substrate rotation slows down to desired speed. In one embodiment, the bevel edge cleaning step 860 generally comprises simultaneous dispensing an etching solution to the bevel edge and dispensing a protection solution to near the center of the substrate while rotating the substrate at a desired speed, such as between about 50 rpm and about 400 rpm, particularly at about 300 rpm.

In one embodiment, the etching solution may be applied to the interface between the production surface and the exclusion zone by the fluid dispensing arm 406. The etching solution may be delivered to the interface at a flow rate of about 40 cc/min. The etching solution may be delivered though a relatively fine nozzle having an aperture with an inner diameter, for example, of between 0.25 and 0.5 inches. Generally, the nozzle that dispenses the etching solution onto the substrate is positioned between about 1 mm and about 3 mm from the substrate surface to allow for precise dispensing of the etching solution onto the interface. Further, the nozzle is generally angled at between about 30° and about 50°, i.e., angled toward the substrate perimeter, to minimize splash back onto the production surface.

The chemical makeup of the etching solution is generally based on H₂SO₄, and therefore, when the concentration of H₂SO₄ is sufficient, the etch rate does not change at a fixed H₂O₂ concentration. Similarly, when the H₂SO₄ concentration is insufficient, the etch rises with H₂SO₄ non-linearly. Further, when H₂SO₄ concentration is sufficient, the etch changes linearly with H₂O₂ concentration, and when the H₂SO₄ concentration is insufficient, the etch rate flattens due to diffusion limited oxidation. Therefore, an exemplary ratio of constituents in an etching solution is between about 15 and 25 parts H₂SO₄, between about 350 and 450 parts H₂O₂, and over 1400 parts H₂O, or about 20 parts H₂SO₄, 400 parts H₂O₂, and 1580 parts H₂O, for example. These concentrations indicate that increasing the acid concentration increases the etch rate, while the peroxide concentration has a minimal effect on the etch rate when increased. Further, when H₂O₂ concentration is less than 6%, oxidation of copper has shown to be slow, and therefore, at these concentrations the etch rate is generally not effected by the H₂SO₄ concentration. However, when H₂O₂ concentration is greater than 6%, copper oxidation is increased, and therefore, the etch rate of high concentration H₂SO₄ rises with H₂O₂ concentrations.

During the bevel edge cleaning step 860, a protection solution, such as DI water, may be dispensed to a central portion of the substrate. In one embodiment, DI water may be dispensed by the fluid dispensing arm 405 positioned over a central portion of the substrate. The DI water may be flown onto the substrate at a rate of between about 60 cc/min to about 100 cc/min. Particularly, the DI water may be flown to the center portion of the substrate at a flow rate of about 70 cc/min. The rotation rate of the substrate facilitates the protection layer being thoroughly spread out and as thin as possible. Further, the rotation rate causes the protection layer to be thin proximate the bevel edge of the substrate where the etching solution is dispensed onto the bevel of the substrate by the etching solution dispensing arm 406. The thickness of the protection layer (preferred to be as thin as possible) at the bevel of the substrate is important to successful bevel cleaning, as a thicker protection layer will dilute the etching solution used to clean the bevel to a point where the etching solution no longer provides an acceptable transition profile for the bevel cleaning process. More particularly, since the protection layer may be formed of DI water, it is desirable to minimize the thickness of the protection layer at the bevel of the substrate, i.e., within about 10 mm of the edge of the substrate, so that the protection layer does not dilute the hydrochloric or the sulfuric acid solution that may be used to clean the bevel edge of the substrate.

After the bevel edge cleaning step 860 has completed, a rinse step 870 may be performed. During the rinse step 870, dispensing of the etching solution may be terminated and a rinsing solution is flown to the rotating substrate. In one embodiment, the rinsing solution is DI water. In the case where DI water is used as the protection solution during the bevel edge cleaning step 860, the DI water flow rate may be increased in the rinse step 870. In one embodiment, the rinse solution, such as DI water, may be dispensed to the substrate at a flow rate of about 1200 cc/min. In one embodiment, the substrate rotation speed may remain the same as during the bevel edge cleaning step 860. In another embodiment, a rinse solution may be dispensed onto the back surface of the.

While the foregoing is directed to embodiments of the present invention, other and further embodiments of the invention may be devised without departing from the basic scope thereof, and the scope thereof is determined by the claims that follow.

1. A method for cleaning a bevel edge of a semiconductor substrate, comprising:
centering the semiconductor substrate on a central axis of a substrate support member;
rotating the semiconductor substrate on the substrate support member about the central axis;
dispensing an etching solution onto the bevel edge of a production surface of the semiconductor substrate with a first pivotally mounted fluid dispensing nozzle; and
simultaneously with the dispensing of the etching solution, dispensing a protective fluid onto a central portion of the production surface with a second pivotally mounted fluid dispensing nozzle.

2. The method of claim 1, wherein the etching solution is at least one of hydrochloric acid, sulfuric acid, and combinations thereof.

3. The method of claim 1, wherein the protective fluid comprises deionized water.

4. The method of claim 1, wherein rotating the semiconductor substrate comprises rotating comprises rotating the semiconductor substrate between about 50 rpm and about 400 rpm.

5. The method of claim 3, wherein rotating the semiconductor substrate comprises rotating comprises rotating the semiconductor substrate at about 300 rpm.

6. The method of claim 1, wherein dispensing the protective solution comprises dispensing the protective solution between about 60 cc/min and about 100 cc/min.

7. The method of claim 6, wherein dispensing the protective solution comprises dispensing the protective solution at about 70 cc/min.

8. The method of claim 1, wherein centering the semiconductor substrate comprises:
receiving the semiconductor substrate with three centering posts, each of the three centering posts having an off-centered centering pin;
rotating the three centering posts to move the corresponding centering pins inwardly; and
engaging the semiconductor substrate with the centering pins.

9. The method of claim 8, wherein rotating the three centering posts comprises using a frictionless actuator.

10. A method for removing unwanted metal deposits from a bevel edge of a substrate, comprising:
centering the substrate on a central axis of a substrate support member;
securing the substrate on the substrate support member;
rotating the substrate on the substrate support member about the central axis at a rate of between about 50 rpm and about 400 rpm;
dispensing a protective fluid onto a production surface of the substrate; and
dispensing an edge bead removal solution onto the bevel edge of the production surface simultaneously with the dispensing of the protective fluid.

11. The method of claim 10, wherein securing the substrate comprises:
receiving the substrate with three centering posts, each of the three centering posts having an off-centered centering pin;
rotating the three centering posts to move the corresponding centering pins inwardly; and
engaging the substrate with the centering pins.

12. The method of claim 10, wherein dispensing the protective fluid comprises positioning a pivotally mounted fluid dispensing arm above a central portion of the substrate and dispensing the protective fluid onto the central portion of the substrate from a fluid aperture positioned on a distal end of the fluid dispensing arm.

13. The method of claim 12, wherein the protective fluid comprises deionized water.

14. The method of claim 10, wherein dispensing the edge bead removal solution comprises positioning a fluid dispensing nozzle extending from a distal end of a pivotally mounted etching dispensing arm above the bevel edge of the substrate and dispensing the edge bead removal solution from the nozzle onto the bevel edge.

15. The method of claim 14, wherein the edge bead removal solution comprises at least one of H₂SO₄ and H₂O₂.

16. The method of claim 13, wherein dispensing the deionized water onto the production surface of the substrate is performed at a flow rate of about between 60 cc/min to about 100 cc/min.

17. The method of claim 13, wherein dispensing the deionized water onto the production surface of the substrate is performed at a flow rate of about 70 cc/min.

18. The method of claim 10, wherein rotating the substrate support member is performed at a rate of about 300 rpm.

19. The method of claim 10, further comprising:
dispensing deionized water to the substrate to pre-rinse the substrate; and
drying the substrate by rotating the substrate at a rate of between about 2000 rpm to about 3500 rpm.

20. The method of claim 10, further comprising dispensing the protective fluid at an increasing a flow rate upon terminating the edge bead removal solution.
